(19) United States
(12) Patent Application Publication
(10) Pub. No.: US 2026/0343851 A1
(43) Pub. Date: Oct. 29, 2026

(54) NON-VOLATILE MEMORY DEVICE AND AN OPERATING METHOD THEREOF

(71) Applicant: MACRONIX INTERNATIONAL CO., LTD., Hsinchu (TW)

(72) Inventors: Wei-Chen CHEN, Taoyuan County (TW); Hang-Ting LUE, Zhubei City (TW)

(21) Appl. No.: 19/188,118

(22) Filed: Apr. 24, 2025

(51) Int. Cl. H10B 12/10; G11C 11/39

(52) U.S. Cl. CPC H10B 12/10; G11C 11/39

(57) ABSTRACT

A non-volatile memory device and an operation thereof are disclosed. The method for operating the non-volatile memory device comprises: performing a dynamic random-access memory (DRAM) mode operation on the non-volatile memory device; performing a non-volatile memory (NVM) mode storage operation on the non-volatile memory device; and before the non-volatile memory device is powered off, regularly performing a store operation for storing a DRAM data in the non-volatile memory device.

### TECHNICAL FIELD

The disclosure relates to a non-volatile memory device and an operating method thereof.

### BACKGROUND

The Gate-Controlled Thyristor (GCT) is an improved type of thyristor, characterized by enhanced gate control capability, enabling faster switching and reduced power loss.

Non-volatile random access memory (nvRAM) is a type of memory that retains data even after power is lost while still allowing random access. nvRAM combines the fast access speed of RAM with the non-volatility of storage, making it widely used in devices that require both rapid data access and data retention.

Types of nvRAM include non-volatile static random access memory (nvSRAM) and non-volatile dynamic random access memory (nvDRAM). However, nvSRAM has drawbacks such as large cell size and low memory density, while nvDRAM suffers from poor scalability.

Therefore, there is a need for a non-volatile memory device and its operating method to address the shortcomings of existing non-volatile random access memory.

### SUMMARY

According to one embodiment, a non-volatile memory device is provided. The non-volatile memory device includes: a substrate; a first gate structure, a second gate structure, and a third gate structure, disposed on the substrate, separated from each other in a first direction, and extending along a second direction; and a plurality of channel bodies, separated from each other in the second and a third direction, and respectively passing through the first gate structure, the second gate structure, and the third gate structure along the first direction. The first direction, the second direction, and the third direction are mutually orthogonal, an upper surface of the substrate is parallel to the first and the second directions, and the upper surface is perpendicular to the third direction. A material of the second gate structure includes an oxide-nitride-oxide (ONO) layer or a ferroelectric thin film.

According to another embodiment, a method for operating a non-volatile memory device is provided. The method for operating the non-volatile memory device comprises: performing a dynamic random-access memory (DRAM) mode operation on the non-volatile memory device; performing a non-volatile memory (NVM) mode storage operation on the non-volatile memory device; and before the non-volatile memory device is powered off, regularly performing a store operation for storing a DRAM data in the non-volatile memory device.

### BRIEF DESCRIPTION OF THE DRAWINGS

FIG. 1 illustrates a perspective schematic diagram of a non-volatile memory device according to an embodiment of the present invention.

FIG. 2 illustrates a cross-sectional schematic diagram of the second gate structure of the non-volatile memory device according to one embodiment.

FIG. 3 illustrates the equivalent circuit diagram of the non-volatile memory device according to an embodiment of the present invention.

FIG. 4A illustrates a flowchart for an operational method of the non-volatile memory device according to one embodiment of this application.

FIG. 4B illustrates the current-voltage characteristic curve of the non-volatile memory device according to one embodiment of this application.

FIG. 5A illustrates a schematic diagram of the DRAM mode operation of the non-volatile memory device according to one embodiment of this invention.

FIG. 5B shows that in one embodiment of the application, the non-volatile memory device is either the HRS state or the LRS state.

FIG. 6A illustrates a schematic diagram of the store-to-NVM operation of the non-volatile memory device according to one embodiment of this invention.

FIG. 6B shows a simulation diagram of the channel potential and

the coupling efficiency according to one embodiment of this invention.

FIG. 6C shows the electron density in the channel of the second gate structure G2 under NVM “1” and NVM “0” conditions.

FIG. 7 shows the NVM retention time simulation diagram of the non-volatile memory device in an embodiment of this invention.

FIG. 8A shows the current-voltage characteristic curve of the non-volatile memory device in an embodiment of this invention.

FIG. 8B shows the current-voltage characteristic curve along with the energy band-position diagram of the non-volatile memory device in an embodiment of this invention.

FIG. 9 shows the simulation diagram of the NVM erase operation of the non-volatile memory device in an embodiment of this invention.

FIG. 10 shows the curve of threshold voltage versus the absolute value of G2 bias in an embodiment of this invention.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

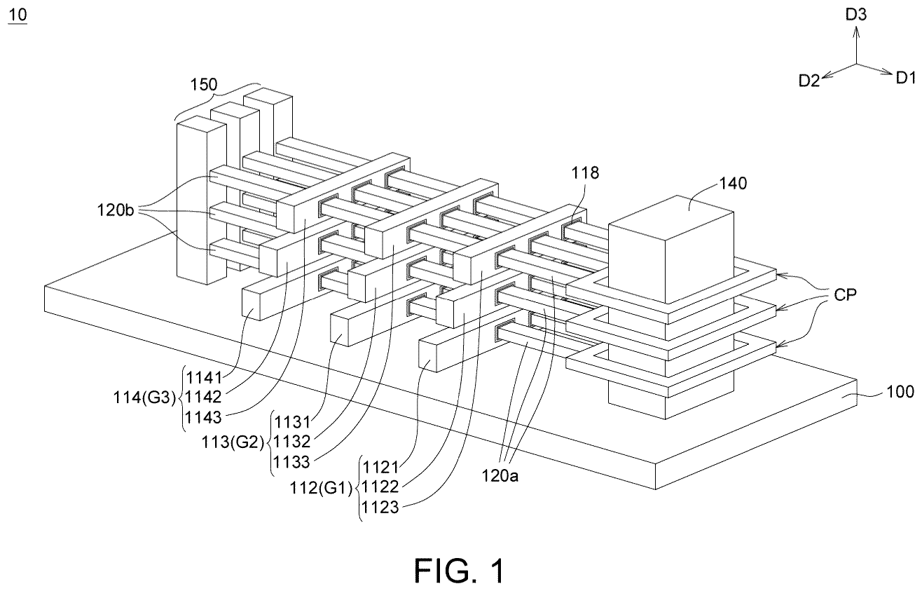

FIG. 1 illustrates a perspective schematic diagram of a non-volatile memory device 10 according to an embodiment of the present invention. The non-volatile memory device 10 includes a substrate 100, a first gate structure 112 (also referred to as the first gate G1), a second gate structure 113 (also referred to as the second gate structure G2), a third gate structure 114 (also referred to as the third gate G3), multiple channel bodies (also referred as channels) 120, multiple contact pads CP, a first-side plug 140, and multiple second-side plugs 150. To simplify the illustration, FIG. 1 omits certain insulating materials. For example, the insulating materials between the substrate 100, channel bodies 120, first gate structure 112, second gate structure 113, and third gate structure 114 are not shown.

As shown in FIG. 1, the first gate structure 112, the second gate structure 113, and the third gate structure 114 are disposed on the substrate 100, separated from each other along a first direction D1 (e.g., the Y direction) and extending along a second direction D2 (e.g., the X direction). In other words, the non-volatile memory device 10 of this embodiment includes three gate structures: the first gate structure 112, the second gate structure 113, and the third gate structure 114. The operation of the non-volatile memory device 10 is controlled by applying gate voltages to the first gate structure 112, the second gate structure 113, and the third gate structure 114. The channel bodies 120 are separated from each other along the second direction D2 and a third direction D3 (e.g., the Z direction) and extend along the first direction D1, passing through the first gate structure 112, the second gate structure 113, and the third gate structure 114. As shown in FIG. 1, the first direction D1, the second direction D2, and the third direction D3 intersect each other. The upper surface of the substrate 100 is parallel to the first direction D1 and the second direction D2, while the normal direction of the upper surface of the substrate 100 is parallel to the third direction D3. The first direction D1, the second direction D2, and the third direction D3 are substantially perpendicular to one another. The channel bodies 120 may be orthogonal to the first gate structure 112, the second gate structure 113, and the third gate structure 114.

In FIG. 1, the first gate structure 112, the second gate structure 113, and the third gate structure 114, for example, have asymmetric widths (though the present disclosure is not limited to this). The width is measured along the first direction D1. For example, in the first direction D1, the first width of the first gate structure 112, the second width of the second gate structure 113, and the third width of the third gate structure 114 are different from each other. For instance, the first width is smaller than the second width, and the second width is smaller than the third width. However, the present invention is not limited to this configuration.

Additionally, in this embodiment, the first gate structure 112 includes multiple sections 1121 to 1123, and these sections 1121 to 1123 have the same width along the first direction D1. Each section 1121 to 1123 of the first gate structure 112 extends along the second direction D2 and is separated from each other along the third direction D3, for example, by an insulating material (not shown) such that they do not directly contact each other. The lengths of sections 1121 to 1123 of the first gate structure 112 along the second direction D2 are different. For example, the lengths of sections 1121 to 1123 decrease sequentially along the second direction D2, meaning that section 1121 is longer than section 1122 along the second direction D2, and section 1122 is longer than section 1123 along the second direction D2.

The second gate structure 113 includes multiple sections 1131 to 1133, and these sections 1131 to 1133 have the same width along the first direction D1. Each section 1131 to 1133 of the second gate structure 113 extends along the second direction D2 and is separated from each other along the third direction D3, for example, by an insulating material (not shown) such that they do not directly contact each other. The lengths of sections 1131 to 1133 of the second gate structure 113 along the second direction D2 are different. For example, the lengths of sections 1131 to 1133 decrease sequentially along the second direction D2, meaning that section 1131 is longer than section 1132 along the second direction D2, and section 1132 is longer than section 1133 along the second direction D2.

The third gate structure 114 includes multiple sections 1141 to 1143, and these sections 1141 to 1143 have the same width along the first direction D1. Each section 1141 to 1143 of the third gate structure 114 extends along the second direction D2 and is separated from each other along the third direction D3, for example, by an insulating material (not shown) such that they do not directly contact each other. Similarly, the lengths of sections 1141 to 1143 along the second direction D2 are different. The lengths of sections 1141 to 1143 decrease sequentially along the second direction D2, meaning that section 1141 is longer than section 1142 along the second direction D2, and section 1142 is longer than section 1143 along the second direction D2.

As shown in FIG. 1, the contact pads CP are stacked along the third direction D3 and are separated from each other along the third direction D3. Each contact pad CP is connected to a corresponding first end 120a of a channel body 120. For example, each contact pad CP is connected to the first ends 120a of three channel bodies 120 that overlap in the second direction D2.

The first-side plug 140 extends along the third direction D3 and connects all the contact pads CP. The second-side plugs 150 extend along the third direction D3 and are separated from each other along the second direction D2. Each second-side plug 150 is connected to a corresponding second end 120b of a channel body 120. For example, each second-side plug 150 is connected to the second ends 120b of three overlapping channel bodies 120 along the third direction D3. The second end 120b is opposite to the first end 120a, meaning that the first end 120a and the second end 120b are the two opposite ends of the channel body 120 along the first direction D1. The first gate structure 112 is closer to the first end 120a than the third gate structure 114, while the third gate structure 114 is closer to the second end 120b than the first gate structure 112. The second gate structure 113 is positioned between the third gate structure 114 and the first gate structure 112. In one embodiment, the first end 120a includes a first conductivity-type dopant, and the second end 120b includes a second conductivity-type dopant that is different from the first conductivity-type dopant. The first conductivity-type dopant is N-type dopant, and the second conductivity-type dopant is P-type dopant. For example, the first end 120a may include a high-concentration N-type dopant (N+), and the second end 120b may include a high-concentration P-type dopant (P+).

Additionally, each section 1121 to 1123 of the first gate structure 112 may surround multiple channel bodies 120 and dielectric layers 118 (for example but not limited by, the three channel bodies 120 and the dielectric layers 118 of the same layer), forming three gate-all-around (GAA) structures. Each section 1131 to 1133 of the second gate structure 113 may surround multiple channel bodies 120 and dielectric layers 118 (for example but not limited by, the three channel bodies 120 and the dielectric layers 118 of the same layer), forming three gate-all-around (GAA) structures. Each section 1141 to 1143 of the third gate structure 114 may surround multiple channel bodies 120 and dielectric layers 118 (for example but not limited by, the three channel bodies 120 and the dielectric layers 118 of the same layer), forming three gate-all-around (GAA) structures.

The sections 1121 to 1123 of the first gate structure 112, the sections 1131 to 1133 of the second gate structure 113 and the sections 1141 to 1143 of the third gate structure 114 can have independently applied biases, allowing for independent adjustment of word line bias for different pages, enabling page erase and reducing disturbances and retention issues in unselected pages.

The non-volatile memory device 10 in this embodiment is a 3D stacked GCT nvDRAM with the following component characteristics. (1) It utilizes P+bit lines (BL) and N+source lines (SL) to achieve DRAM operation based on a thyristor. (2) The gate dielectric layer of the second gate (G2) includes an ONO (oxide-nitride-oxide) layer or a ferroelectric thin film to enable non-volatile memory (NVM) functionality. The ONO layer can also be designed using band-gap engineering, where the tunneling dielectric layer consists of multiple layers of oxides and nitrides. (3) The dielectric layers of the first gate (G1) and the third gate (G3) can be ONO, ferroelectric material, or a simple oxide. (4) Three word lines are used (where G1 and G3 act as selectors) to activate the self-boosting principle during the storage process. (5) It supports a recall-free operation mode. These details will be further explained below.

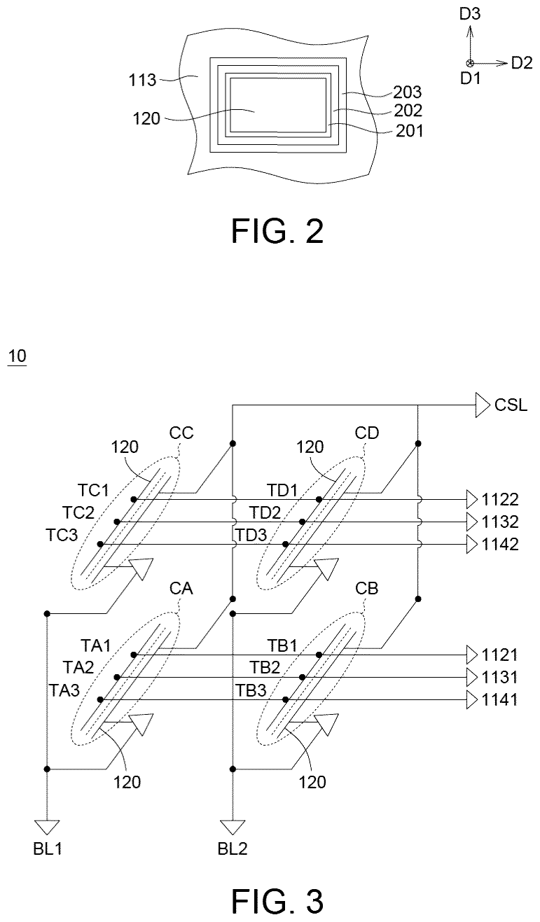

FIG. 2 illustrates a cross-sectional schematic diagram of the second gate structure 113 (also referred to as the second gate structure G2) of the non-volatile memory device 10 according to one embodiment. As shown in FIG. 2, the second gate structure 113 includes: a tunnel dielectric layer 201 (implemented using an oxide); a charge-trapping layer 202 (implemented using a nitride); and a blocking dielectric layer 203 (implemented using an oxide). Thus, the second gate structure 113 adopts an ONO (oxide-nitride-oxide) architecture. In other possible implementations, the second gate structure 113 may be realized using a ferroelectric thin film.

FIG. 3 illustrates the equivalent circuit diagram of the non-volatile memory device 10 according to an embodiment of the present invention. According to one embodiment, the non-volatile memory device 10 further includes multiple memory cells (such as memory cells CA~CD shown in FIG. 3). Each memory cell (e.g., memory cells CA~CD) is formed by the following components: a corresponding portion of the channel body 120, the first gate structure 112, the second gate structure 113 and the third gate structure 114, as shown in the equivalent circuit diagram in FIG. 3.

As shown in FIG. 3, for example, the intersection positions of the channel body 120 with the section 1121 of the first gate structure 112, the section 1131 of the second gate structure 113, and the section 1141 of the third gate structure 114 respectively form transistors TA1, TA2, and TA3. As shown in FIG. 3, the transistors TA1, TA2, and TA3, connected by the same channel body 120, form the memory cell CA; the transistors TB1, TB2, and TB3, connected by the same channel body 120, form the memory cell CB; the transistors TC1, TC2, and TC3, connected by the same channel body 120, form the memory cell CC; and the transistors TD1, TD2, and TD3, connected by the same channel body 120, form the memory cell CD. The first end 120a of the channel body 120 is connected to the corresponding first side pad CP. The first side pads CP of different layers are electrically connected to the first side plug 140, which in turn is electrically connected to the source line. Thus, memory cells CA~CD are all connected to a common source line CSL (i.e., at the same potential). The second end 120b of the channel body 120 is connected to the corresponding second side plug 150. That is, the channel bodies 120 that overlap in the third direction D3 are connected to the same second side plug 150. The second side plug 150 may function as a bit line. For example, memory cells CA and CC are electrically connected to the first bit line BL1; and memory cells CB and CD are electrically connected to the second bit line BL2.

Please refer back to FIG. 1. According to this embodiment, the first gate structure 112, second gate structure 113, and third gate structure 114 can each serve as multiple word lines (WL). For example, each section 1121~1123 of the first gate structure 112 can serve as one word line, meaning the first gate structure 112 corresponds to three word lines. Each section 1131~1133 of the second gate structure 113 can serve as one word line, meaning the second gate structure 113 corresponds to three word lines. Each section 1141~1143 of the third gate structure 114 can serve as one word line, meaning the third gate structure 114 corresponds to three word lines.

The first side plug 140 serves as the common source line (CSL). Each second side plug 150 serves as a bit line (BL).

In some embodiments, the substrate 100 may include a semiconductor substrate, such as a bulk silicon substrate. In this embodiment, the channel body 120 may be formed by a selective epitaxial growth process, and the material of the channel body 120 may include single-crystal silicon. During the operation (e.g., programming or erasing) of the non-volatile memory device 10, the channel body 120 may be used to store carriers (e.g., electrons or holes). The dielectric film 118 does not need to have the function of storing carriers (e.g., electrons or holes), so the dielectric film 118 does not include a charge storage structure, such as an ONO (oxide-nitride-oxide) structure. In one embodiment, the material of the dielectric film 118 includes a dielectric material, such as an oxide, and the dielectric film 118 may be a single-layer structure. In one embodiment, the material of the dielectric film 118 may include a high dielectric constant material (high-k material). In one embodiment, the materials of the first side plug 140, second side plug 150, first gate structure 112, second gate structure 113, and third gate structure 114 may include semiconductor materials or metal materials. It should be understood that the materials of the components of the present invention are not limited to the above-mentioned materials.

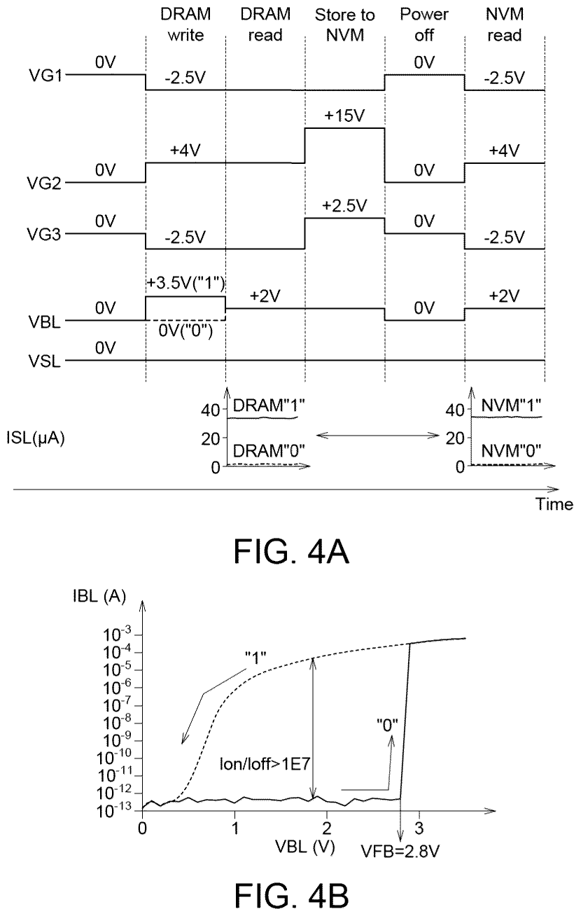

FIG. 4A illustrates a flowchart for an operational method of the non-volatile memory device 10 according to one embodiment of this application. FIG. 4B illustrates the current-voltage characteristic curve of the non-volatile memory device 10 according to one embodiment of this application. The voltage values in FIG. 4A are provided for illustrative purposes only and are not intended to limit this application.

As shown in FIG. 4A, during the DRAM write operation, the voltages VG1, VG2, and VG3 applied to the three gates G1, G2, and G3 are −2.5V, +4V, and −2.5V, respectively. The voltage VBL applied to the bit line is +3.5V (for writing “1”) or OV (for writing “0”). The voltage VSL applied to the source line is OV. Here, the “DRAM write operation” refers to treating the non-volatile memory device 10 as a DRAM for writing operations.

As shown in FIG. 4A, during the DRAM read operation, the voltages VG1, VG2, and VG3 applied to the three gates G1, G2, and G3 are −2.5V, +4V, and −2.5V, respectively. The voltages VBL and VSL applied to the bit line and source line are +2V and OV, respectively. Here, the “DRAM read operation” refers to treating the non-volatile memory device 10 as a DRAM for reading operations. The “DRAM write operation” and “DRAM read operation” can also be collectively referred to as “DRAM mode operations.”

As shown in FIG. 4A, during the store-to-NVM operation, the voltages VG1, VG2, and VG3 applied to the three gates G1, G2, and G3 are −2.5V, +15V, and +2.5V, respectively. The voltages VBL and VSL applied to the bit line and source line are +2V and OV, respectively. Here, the “store-to-NVM operation” refers to treating the non-volatile memory device 10 as a non-volatile memory for storing data. The “store-to-NVM operation” can also be referred to as the “non-volatile memory mode storage operation.”

As shown in FIG. 4A, when power is cut off, all voltages VG1, VG2, VG3, VBL, and VSL are, of course, OV.

As shown in FIG. 4A, during the NVM read operation, the voltages VG1, VG2, and VG3 applied to the three gates G1, G2, and G3 are −2.5V, +4V, and −2.5V, respectively. The voltages VBL and VSL applied to the bit line and source line are +2V and OV, respectively. The “NVM read operation” refers to treating the non-volatile memory device 10 as a non-volatile memory for reading. During the “NVM read operation,” the NVM state (1 or 0) is read to confirm whether it matches the DRAM state (1 or 0). Here, the NVM state refers to the state stored in the non-volatile memory device 10 during the store-to-NVM operation. The DRAM state (or said DRAM data) refers to the state (or data) written into the non-volatile memory device 10 during the DRAM write operation. As shown in the source current ISL at the bottom of FIG. 4A, when the DRAM state is 1, reading the non-volatile memory device 10 results in a high current. When the DRAM state is 0, reading the non-volatile memory device 10 results in a low current. A DRAM state of 1 corresponds to an NVM state of 1, and a DRAM state of 0 corresponds to an NVM state of 0. As shown in the source current ISL at the bottom of FIG. 4A, when the NVM state is 1, reading the non-volatile memory device 10 results in a high current. When the NVM state is 0, reading the non-volatile memory device 10 results in a low current. This proves that, in one embodiment of this invention, the NVM state is identical to the DRAM state.

Additionally, in one embodiment of this invention, the NVM read operation is an optional step. Since the purpose of the NVM read operation is to verify whether the NVM state matches the DRAM state, omitting the NVM read operation does not affect the results of the DRAM write, DRAM read, and store-to-NVM operations in the non-volatile memory device 10.

It should be noted that the sequence of operations shown in FIG. 4A (DRAM write, DRAM read, store-to-NVM, power-off, and NVM read) does not limit the operation of the non-volatile memory device 10 in this embodiment. That is, under normal circumstances, after multiple DRAM write and DRAM read operations, one or more store-to-NVM operations can be performed. In this way, even if power is lost, the data stored in the non-volatile memory device 10 will persist and not be lost.

In FIG. 4B, it can be observed that, when the non-volatile memory device 10 is written with a “1,” the bit line current IBL has a high current (Ion). When the non-volatile memory device 10 is written with a “0,” the bit line current IBL has a low current (Ioff). The ratio of the high current (Ion) to the low current (Ioff) of the bit line current IBL is approximately 1E7 (1×10⁷). Additionally, VFB represents the Forward Break-over Voltage. VFB is the voltage at which a thyristor automatically turns on due to an increase in forward voltage, without an externally applied gate trigger current. Since the device automatically conducts when the applied gate voltage exceeds this value, no gate trigger is required.

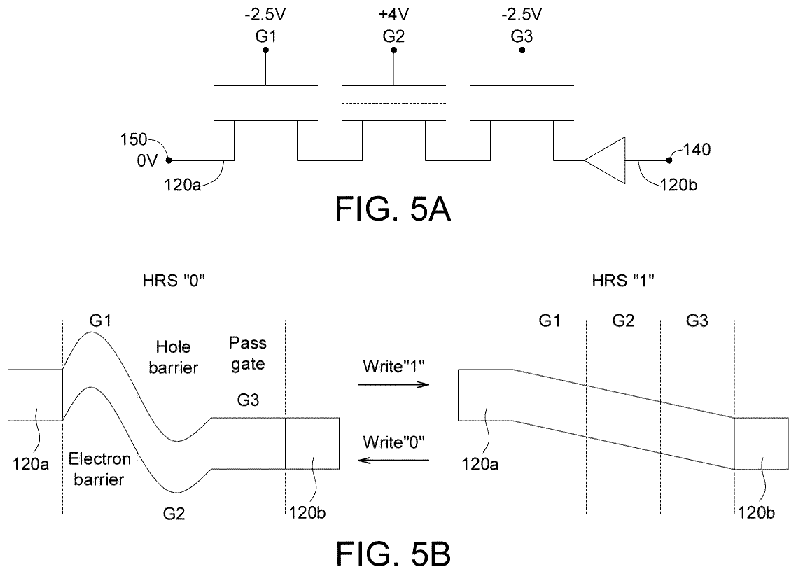

FIG. 5A illustrates a schematic diagram of the DRAM mode operation of the non-volatile memory device 10 according to one embodiment of this invention. As shown in FIG. 5A, during the DRAM mode operation of the non-volatile memory device 10, the voltages VG1, VG2, and VG3 applied to the three gates G1, G2, and G3 are −2.5V, +4V, and −2.5V, respectively. When writing “1”, the bit line voltage VBL applied to the bit line must be higher than the forward break-over voltage VFB to induce forward break-over, thereby locking the memory cell of the non-volatile memory device 10 into “1” (also referred to as the low resistance state (LRS)). When writing “0”, the bit line voltage VBL is set to OV, restoring the potential barrier and this locks the memory cell of the non-volatile memory device 10 into “0” (also referred to as the high resistance state (HRS)). For DRAM read operations, the bit line voltage VBL is set between the holding voltage (approximately 0.4V) and VFB for reading the bit line current IBL.

FIG. 5B shows that in one embodiment of the application, the non-volatile memory device 10 is either the HRS state or the LRS state. As shown in FIG. 5B, a bit line voltage higher than VFB eliminates the potential barrier (hole barrier or electron barrier), making the non-volatile memory device 10 enter the LRS state. A bit line voltage of OV induces a potential barrier (hole barrier or electron barrier), making the non-volatile memory device 10 enter the HRS state.

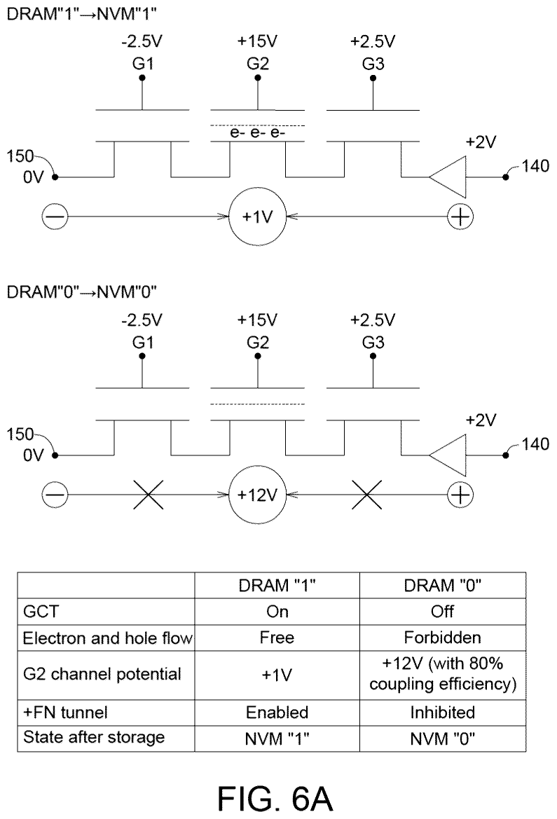

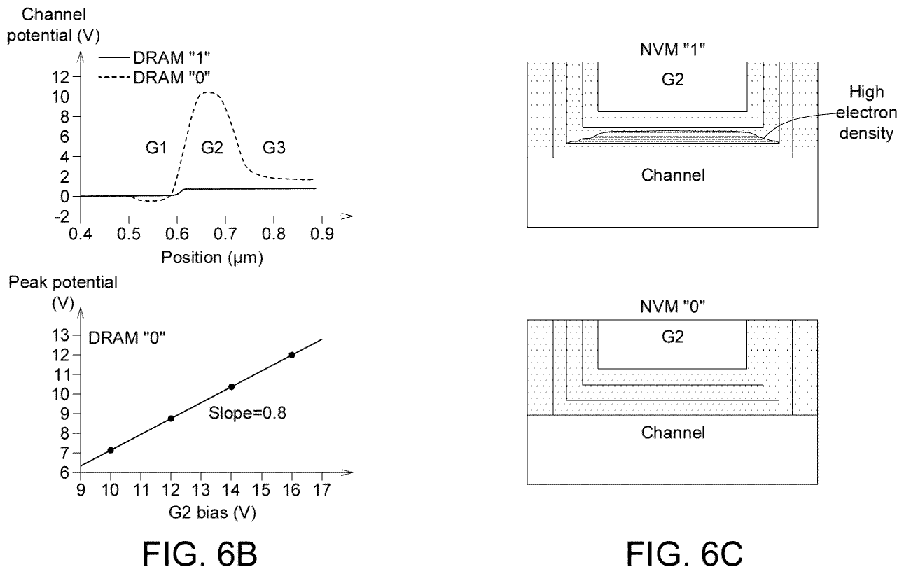

FIG. 6A illustrates a schematic diagram of the store-to-NVM operation of the non-volatile memory device 10 according to one embodiment of this invention. When storing DRAM “1” into NVM “1”, the gate control transistor (GCT) is on, allowing free movement of electrons and holes; and the bias voltage of the second gate structure G2 is +15V. Since this state is LRS, the channel voltage of the second gate structure G2 is approximately half of the bit line voltage VBL (+2V), which is about +1V. The voltage difference across the second gate structure G2 (from the bias voltage to the channel voltage) is about 14V, which causes positive Fowler-Nordheim (FN) tunneling, storing a large amount of charge in the channel of the second gate structure G2, thereby achieving an NVM “1” state.

Conversely, when storing DRAM “0” as NVM “0”, the gate control transistor (GCT) is off, preventing the movement of electrons and holes. The bias voltage of the second gate structure G2 is +15V. Since this state is HRS, the channel of the second gate structure G2 is floating. Assuming a coupling efficiency of 0.8, the channel voltage of the second gate structure G2 is approximately 80% of the bias voltage (15V×0.8=12V). The voltage difference across the second gate structure G2 (from the bias voltage to the channel voltage) is about 15V-12V=3V. This is insufficient for positive FN tunneling, so no significant charge is stored in the channel of the second gate structure G2, thereby achieving an NVM “0” state.

FIG. 6B shows a simulation diagram of the channel potential and the coupling efficiency according to one embodiment of this invention. As illustrated in FIG. 6B, during the “store-to-NVM operation,” the channel surface potential exhibits a unique self-boosting characteristic for the DRAM “0” state. The significant difference between DRAM “1” and “0” satisfies the requirements of the “store-to-NVM operation.”

From the simulation diagram of coupling efficiency at the bottom of FIG. 6B, it can be observed that the peak surface potential of DRAM “0” is a function of the bias voltage of the second gate structure G2, which exhibits 80% coupling efficiency.

FIG. 6C shows the electron density in the channel of the second gate structure G2 under NVM “1” and NVM “0” conditions. Therefore, from FIG. 6C, it can be seen that electrons are trapped in the charge trapping layer only in the DRAM “1” (NVM “1”) state, while the self-boosting mechanism causes the trapped electrons to disappear in the DRAM “0” (NVM “0”) state.

In other words, in an embodiment of this invention, writing DRAM “1” means setting the memory cell (such as memory cell CA in FIG. 3) to the ON state (LRS), while writing DRAM “0” means setting the memory cell (such as memory cell CA in FIG. 3) to the OFF state (HRS). Furthermore, in this embodiment, storing DRAM “1” to NVM means trapping electrons in the second gate structure G2 of the GCT, whereas storing DRAM “0” to NVM means removing the trapped electrons so that electrons are essentially absent in the second gate structure G2 of the GCT.

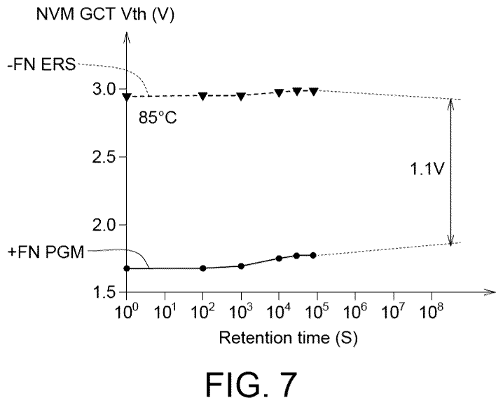

FIG. 7 shows the NVM retention time simulation diagram of the non-volatile memory device 10 in an embodiment of this invention. Here, +FN PGM represents programming, and −FN ERS represents erasure. As seen in FIG. 7, in NVM mode, the memory cell of the non-volatile memory device 10 in this embodiment exhibits high-temperature retention characteristics, demonstrating that after 10 years of high-temperature baking at 85 °C, a voltage window of 1.1V can still be obtained.

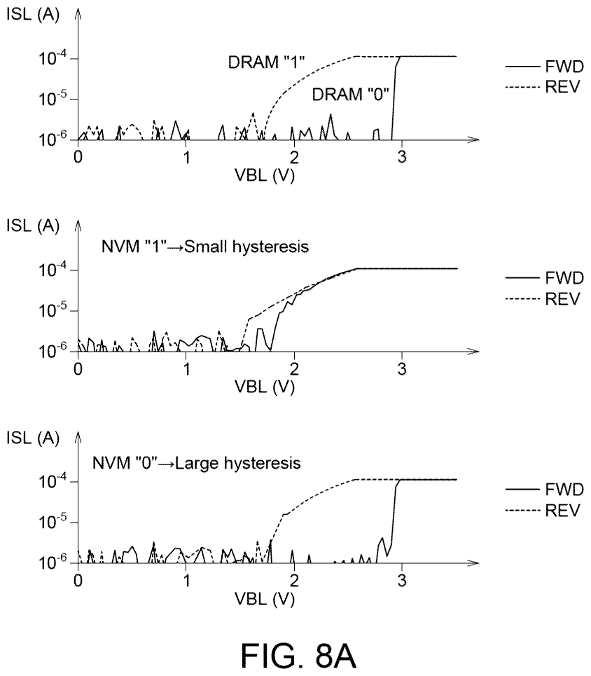

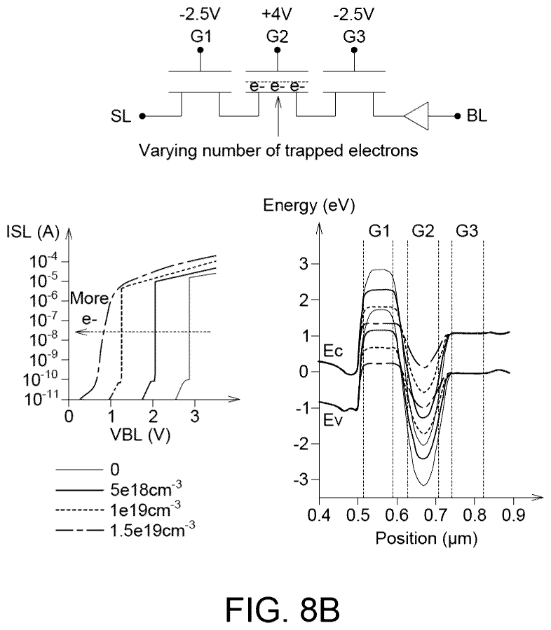

FIG. 8A shows the current-voltage characteristic curve of the non-volatile memory device 10 in an embodiment of this invention. FIG. 8B shows the current-voltage characteristic curve along with the energy band-position diagram of the non-volatile memory device 10 in an embodiment of this invention.

As shown in FIG. 8A, when the ONO layer of the second gate structure G2 captures electrons (i.e., in the NVM “1” state), a slight hysteresis effect occurs, and only LRS is observed, corresponding to the “1” state of DRAM. Conversely, if the ONO layer of the second gate structure G2 does not capture electrons (i.e., in the NVM “0” state), a typical hysteresis phenomenon is observed. This indicates that as long as the bit-line voltage VBL is lower than the forward break-over voltage VFB, the DRAM will remain in the “0” state. This function establishes the basis for the recall-free operation of the memory cell (nvDRAM) in the non-volatile memory device 10 in this embodiment, as the NVM state (whether electrons are trapped in G2) determines the DRAM state, thereby eliminating the need for an additional recall step (in conventional technology, after power loss, a recall step is required to restore data from NVM back to DRAM).

As shown in FIG. 8B, the simulated curve of source current ISL relative to bit-line voltage VBL, along with the energy band diagram of the SONOS layer in the second gate structure G2 with different numbers of trapped electrons, is presented. Since the second gate structure G2 modulates the hole barrier, an increase in the number of trapped electrons effectively reduces the hole barrier or electron barrier, leading to a decrease in the forward break-over voltage VFB.

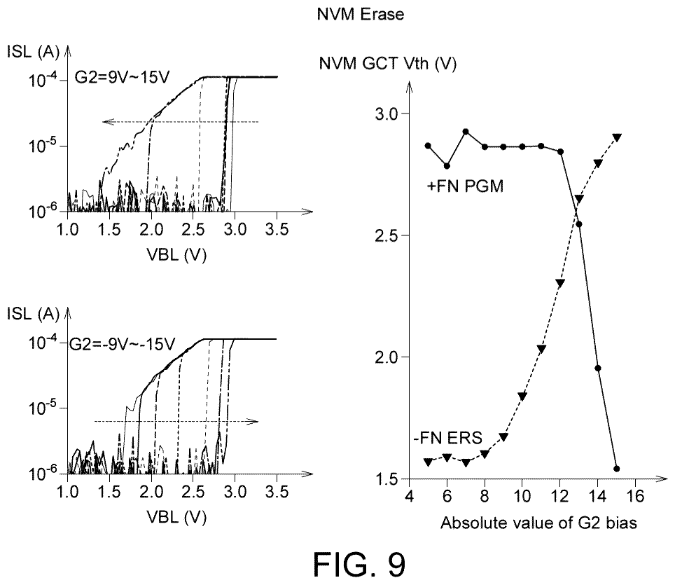

FIG. 9 shows the simulation diagram of the NVM erase operation of the non-volatile memory device 10 in an embodiment of this invention. The simulation diagram illustrates the threshold voltage versus the absolute value of the G2 bias voltage for the memory cell in the non-volatile memory device 10 in NVM mode during +FN programming (+FN PGM) (for “storage”) and −FN erasure (−FN ERS) (for NVM “erasure”).

Additionally, in FIG. 9, for simplicity, only the curve of forward sweeping is shown. During the +FN programming process, as the number of trapped electrons increases, the memory cell transitions from HRS to LRS. During the-FN erasure process, due to hole tunneling, the threshold voltage Vth gradually increases.

When DRAM data is updated, the NVM data should be erased. The −FN erase operation injects holes into the channel of the second gate structure G2 to neutralize the trapped electrons, thereby achieving erasure.

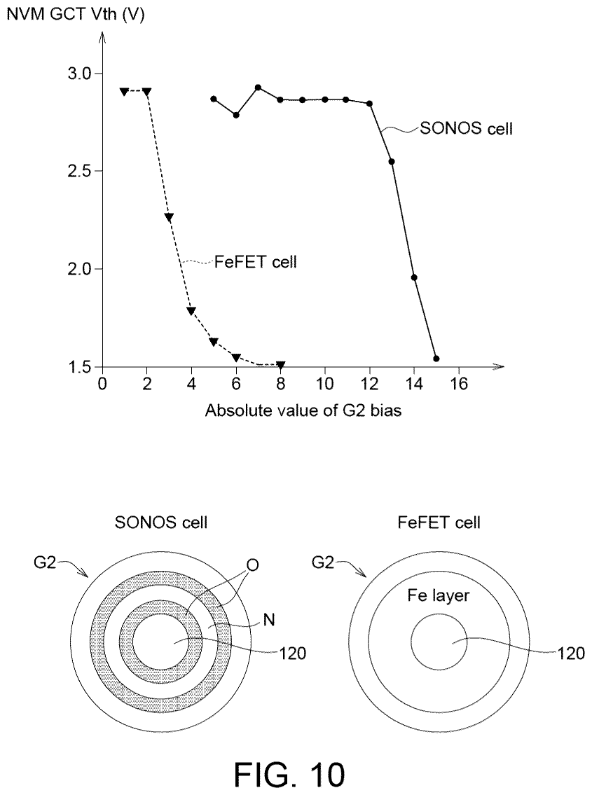

FIG. 10 shows the curve of threshold voltage versus the absolute value of G2 bias in an embodiment of this invention. The curves respectively illustrate the cases where the G2 dielectric layer is made of SONON material (referred to as the SONOS cell) and where the G2 dielectric layer is made of Fe (ferroelectric) material (referred to as the FeFET cell). From the curve, it can be observed that the transient NVM programming characteristics are demonstrated using a G2 structure with SONOS (measured) or FeFET (simulated), where the FeFET architecture can significantly reduce both the programming voltage and delay.

The table below shows a performance comparison between an embodiment of this invention and other conventional examples.

| | Prior | | Prior | | Prior | | One embodiment | | | |
|---|---|---|---|---|---|---|---|---|---|---|
| device | art 1 | | art 2 | | art 3 | | of the application | | | |
| structure | 6T | | 1T1C | | 1T1C | | GCT, 0C | | | |
| NVM | FeCap | | SONOS | | FeCap | | SONOS | | FeFET | |
| | | | | | | | (measured) | | (simulation) | |
| NVM write | 30 | ns | 10 | ms | 90 | ns | 100 | μs | 1 | μs |
| latency | | | | | | | | | | |
| NVM write | 2.4 | V | −3 | V | 2.5 | V | 15 | V | −7 | V |
| voltage | | | | | | | | | | |

| | | | | |
|---|---|---|---|---|
| NVM | 85 °C, | N/A | 55 °C , | 85 °C, |
| retention | 100 | | 10 | 10 |
| | seconds | | years | years |
| RAM | Y | Y | Y | N |
| Destructive | | | | |
| Read | | | | |
| Recall-free | N | N | N | Y |
| Cell size | Large | Medium | Medium | Small |
| | size | size | size | size |

In the table above, “Destructive Read” refers to an operation that alters or erases the original data while reading the memory cell, making it necessary to perform additional recovery (rewrite or refresh) operations to maintain data consistency.

From the above description and the table, it can be concluded that the non-volatile memory device disclosed in this embodiment introduces a capacitor-less 3D nvDRAM based on GCT. One of its key features is the ability to perform recall-free and non-destructive read operations, even in the event of an unexpected power loss. Due to its capacitor-less design, the memory cells in this embodiment's non-volatile memory device have a smaller size. These advantages enable faster boot times and reduced power consumption during startup. This non-volatile memory device has the potential to achieve rapid data backup and boot-up, making it a promising alternative to persistent memory.

Although this disclosure describes many specific details, they should not be interpreted as limitations on the scope of the claimed invention but rather as descriptions of characteristics of specific implementations. Certain features described in the context of a single embodiment may also be implemented in combination within a single embodiment. Conversely, various features described in the context of a single embodiment may also be implemented individually or in any suitable sub combination across multiple embodiments. Additionally, while features may initially be described as functioning in certain combinations or even illustrated as such, in some cases, one or more features may be removed from the combination, and the described combination may apply to a subset or a variation of the subset. Similarly, although operations are depicted in a specific sequence in the illustrations, this should not be understood as requiring those operations to be performed in the exact order shown, nor that all depicted operations must be executed to achieve the desired outcome.

While the above embodiments disclose only a few examples and implementations, modifications, alterations, and enhancements can be made to these and other implementations based on the disclosed content.

In summary, although the invention has been disclosed in terms of embodiments as described above, it is not intended to be limited thereto. Those skilled in the relevant technical field may make various modifications and adaptations without departing from the spirit and scope of the invention. Accordingly, the scope of protection of this invention shall be defined by the appended claims.

What is claimed is:

1. A non-volatile memory device, comprising:
a substrate;
a first gate structure, a second gate structure, and a third gate structure, disposed on the substrate, separated from each other in a first direction, and extending along a second direction; and
a plurality of channel bodies, separated from each other in the second and a third direction, and respectively passing through the first gate structure, the second gate structure, and the third gate structure along the first direction,
wherein the first direction, the second direction, and the third direction are mutually orthogonal, an upper surface of the substrate is parallel to the first and the second directions, and the upper surface is perpendicular to the third direction,
wherein a material of the second gate structure includes an oxide-nitride-oxide (ONO) layer or a ferroelectric thin film.

2. The non-volatile memory device according to claim 1, further comprising:
a plurality of contact pads, stacked along the third direction and separated from each other in the third direction, each contact pad being connected to a corresponding first end of the channel bodies;
a first side plug, extending along the third direction and connecting to the contact pads; and
a plurality of second side plugs, each extending along the third direction and separated from each other in the second direction, each of the second side plugs being connected to a corresponding second end of the channel bodies, the second end being opposite to the first end, wherein the first gate structure is closer to the first end than the second gate structure.

3. The non-volatile memory device according to claim 1, wherein:
the first gate structure comprises a plurality of segments, each of the segments extending along the second direction and separated from each other in the third direction;
the second gate structure comprises a plurality of segments, each of the segments extending along the second direction and separated from each other in the third direction; and
the third gate structure comprises a plurality of segments, each of the segments extending along the second direction and separated from each other in the third direction.

4. The non-volatile memory device according to claim 3, wherein:
the segments of the first gate structure have different lengths in the second direction;
the segments of the second gate structure have different lengths in the second direction; and
the segments of the third gate structure have different lengths in the second direction.

5. The non-volatile memory device according to claim 2, wherein the first end comprises a first conductivity-type dopant, and the second end comprises a second conductivity-type dopant, wherein the second conductivity-type dopant is different from the first conductivity-type dopant.

6. The non-volatile memory device according to claim 5, wherein the first conductivity-type dopant is an N-type dopant, and the second conductivity-type dopant is a P-type dopant.

7. The non-volatile memory device according to claim 3, wherein the segments of the first gate structure, the second gate structure, and the third gate structure are independently biased.

8. The non-volatile memory device according to claim 1, wherein the first gate structure, the second gate structure, and the third gate structure have asymmetric widths in the first direction.

9. The non-volatile memory device according to claim 1, wherein in the first direction, a first width of the first gate structure, a second width of the second gate structure, and a third width of the third gate structure are different from each other, the first width being smaller than the second width, and the second width being smaller than the third width.

10. A method for operating a non-volatile memory device, comprising:
performing a dynamic random-access memory (DRAM) mode operation on the non-volatile memory device;
performing a non-volatile memory (NVM) mode storage operation on the non-volatile memory device; and
before the non-volatile memory device is powered off, regularly performing a store operation for storing a DRAM data in the non-volatile memory device.

11. The method for operating a non-volatile memory device according to claim 10, wherein:
the DRAM mode operation includes a DRAM write operation;
when writing “1” to the non-volatile memory device, a bit line voltage is higher than a forward breakdown voltage to induce forward breakdown, latching a memory cell of the non-volatile memory device into a first impedance state, with a bit line current as a first current; and
when writing “0” to the non-volatile memory device, the bit line voltage is OV, latching the memory cell of the non-volatile memory device into a second impedance state, with a bit line current as a second current, wherein the first current is significantly higher than the second current.

12. The method for operating a non-volatile memory device according to claim 10, wherein the DRAM mode operation includes:
a DRAM read operation,
wherein during the DRAM read operation, a bit line voltage is set between a hold voltage and a forward breakdown voltage, and a bit line current is read.

13. The method for operating a non-volatile memory device according to claim 11, wherein during the NVM mode storage operation,
when storing DRAM “1” to NVM “1,” the memory cell of the non-volatile memory device is latched into the first impedance state, and a channel voltage of the second gate structure is related to a bit line voltage to store charge within a channel of the second gate structure; and
when storing DRAM “0” to NVM “0,” the memory cell of the non-volatile memory device is in the second impedance state, thereby removing charge trapped in the channel of the second gate structure.

14. The method for operating a non-volatile memory device according to claim 10, further comprising:
an NVM read operation, reading out an NVM state to verify whether the NVM state matches a DRAM state.
